(19) United States
(12) Patent Application Publication
(10) Pub. No.: US 2026/0182112 A1
(43) Pub. Date: Jun. 25, 2026

(54) Display Device

(71) Applicant: LG Display Co., Ltd., Seoul (KR)

(72) Inventors: Sungmoo Kim, Paju-si (KR); Dae-Il Kang, Paju-si (KR)

(21) Appl. No.: 19/340,630

(22) Filed: Sep. 25, 2025

(30) Foreign Application Priority Data
Dec. 23, 2024 (KR) 10-2024-0194376

(51) Int. Cl. H10H 29/41; H10H 29/49

(52) U.S. Cl. CPC H10H 29/41; H10H 29/49

(57) ABSTRACT

A display device according to embodiments of the disclosure may comprise a substrate, a first insulation layer disposed on the substrate, a catching portion disposed on the first insulation layer and having a curved side surface convex upward, a light emitting element disposed on the catching portion and overlapping a portion of the catching portion, and a driving line extending along the curved side surface, thereby enhancing light extraction.

### CROSS-REFERENCE TO RELATED APPLICATIONS

This application claims priority from Republic of Korea Patent Application No. 10-2024-0194376, filed on Dec. 23, 2024, which is hereby incorporated by reference for all purposes as if fully set forth herein.

### BACKGROUND

### Field

Embodiments of the disclosure relate to a display device.

### Description of Related Art

As the information society develops, demand for display devices for displaying images is increasing in various forms. Various display devices, such as liquid crystal display devices and organic light emitting display devices, have been utilized in recent years.

The display device may be an LCD display device, an OLED display device, an LED display device, or the like.

The light emission method of the display device may be top emission or bottom emission according to the emission direction.

### BRIEF SUMMARY

Embodiments of the disclosure may provide a display device capable of stably fixing a light emitting element through a catching portion.

Embodiments of the disclosure may provide a display device capable of enhancing luminance as light from the light emitting element is bottom-emitted through the catching portion.

Embodiments of the disclosure may provide a display device capable of enhancing the luminance of light by reflecting the light through a metal.

Embodiments of the disclosure may provide a display device capable of low power consumption by enhancing the luminance of light.

Objects of embodiments of the disclosure are not limited to those set forth herein, and other unmentioned objects would be apparent to one of ordinary skill in the art from the following description.

Embodiments of the disclosure may provide a display device according to embodiments of the disclosure which may comprise a substrate, a first insulation layer disposed on the substrate, a catching portion disposed on the first insulation layer and having a curved side surface convex upward, a light emitting element disposed on the catching portion and overlapping a portion of the catching portion, and a driving line extending along the curved side surface.

The catching portion may include a transparent insulating material.

The catching portion may be formed by an inkjet method.

A viscosity of the catching portion may increase when the catching portion receives light or heat.

The driving line may include an opaque metallic material.

Light directed toward the driving line may be reflected by the driving line.

The light emitting element may overlap an upper surface of the catching portion, and the light emitting element may be embedded in the catching portion.

According to embodiments of the disclosure, there may be provided a display device capable of stably fixing a light emitting element through a catching portion.

According to embodiments of the disclosure, there may be provided a display device capable of enhancing luminance as light from the light emitting element is bottom-emitted through the catching portion.

According to embodiments of the disclosure, there may be provided a display device capable of enhancing the luminance of light by reflecting light through a metal.

According to embodiments of the disclosure, there may be provided a display device capable of low power consumption by enhancing the luminance of light.

The effects of the disclosure are not limited to the foregoing effects, and other effects will be apparent to one of ordinary skill in the art from the following detailed description.

### DESCRIPTION OF DRAWINGS

The disclosure will be more fully understood from the following detailed description and the accompanying drawings, which are provided for illustration only and are not intended to limit the disclosure.

FIG. 1 is a view illustrating a system configuration of a display device according to embodiments of the disclosure.

FIG. 2 is a view illustrating a light emitting element according to embodiments of the disclosure.

FIG. 3 is a view illustrating the viewing angle and luminance of the light emitting element of FIG. 2, according to embodiments of the disclosure.

FIG. 4 is a plan view illustrating a pixel according to embodiments of the disclosure, according to embodiments of the disclosure.

FIG. 5 is a cross-sectional view of area A-B of FIG. 4, according to embodiments of the disclosure.

FIG. 6 is a cross-sectional view of area C-D of FIG. 4, according to embodiments of the disclosure.

### DETAILED DESCRIPTION OF EMBODIMENTS

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” and “comprising” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number etc. of elements, but is used merely to distinguish the corresponding element from other elements.

When it is mentioned that a first element “is connected or coupled to”, “overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, or manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, various embodiments of the disclosure are described in detail with reference to the accompanying drawings.

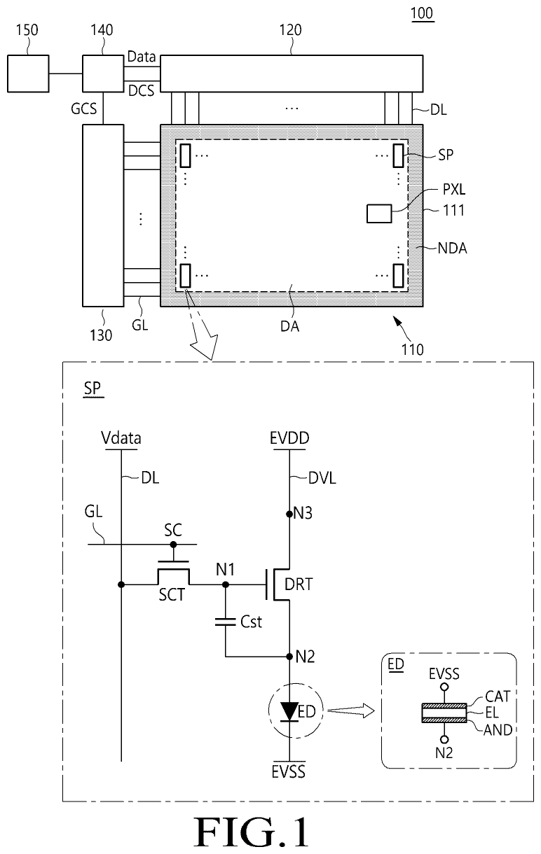

FIG. 1 is a view illustrating a system configuration of a display device 100 according to embodiments of the disclosure.

Referring to FIG. 1, a display device 100 according to embodiments of the disclosure may include a display panel 110 including a plurality of pixels PXL each including a plurality of subpixels SP and driving circuits for driving the plurality of subpixels SP included in the display panel 110.

The driving circuits may include a data driving circuit 120 and a gate driving circuit 130. The display device 100 may further include a controller 140 controlling the data driving circuit 120 and the gate driving circuit 130.

The display panel 110 may include a substrate 111 and signal lines, such as a plurality of data lines DL and a plurality of gate lines GL disposed on the substrate 111. The plurality of data lines DL and the plurality of gate lines GL may be connected to the plurality of subpixels SP.

The display panel 110 may include a display area DA in which images are displayed and a non-display area NDA in which no image is displayed. In the display panel 110, a plurality of subpixels SP for displaying images may be disposed in the display area DA, and the driving circuits 120, 130, and the controller 140 may be electrically connected or disposed in the non-display area NDA. Further, pad units for connection of integrated circuits or a printed circuit may be disposed in the non-display area NDA.

The data driving circuit 120 is a circuit for driving the plurality of data lines DL, and may supply data signals to the plurality of data lines DL.

The gate driving circuit 130 is a circuit for driving the plurality of gate lines GL, and may supply gate signals to the plurality of gate lines GL.

The controller 140 may supply a data control signal DCS to the data driving circuit 120 to control the operation timing of the data driving circuit 120 and may supply a gate control signal GCS to the gate driving circuit 130 to control the operation timing of the gate driving circuit 130.

The controller 140 may start scanning according to a timing implemented in each frame, convert input image data input from the outside into image data Data suited for the data signal format used in the data driving circuit 120, supply the image data Data to the data driving circuit 120, and control data driving at an appropriate time suited for scanning.

The controller 140 receives, from the outside (e.g., a host system 150), various timing signals including a vertical synchronization signal (VSYNC), a horizontal synchronization signal (HSYNC), an input data enable signal (DE), and a clock signal, along with the input image data.

To control the data driving circuit 120 and the gate driving circuit 130, the controller 140 receives timing signals, such as the vertical synchronization signal (VSYNC), horizontal synchronization signal (HSYNC), input data enable signal (DE), and clock signal (CLK), generates various control signals DCS and GCS, and outputs the control signals to the data driving circuit 120 and the gate driving circuit 130.

As an example, to control the gate driving circuit 130, the controller 140 outputs various gate control signals GCS including a gate start pulse (GSP), a gate shift clock (GSC), and a gate output enable signal (Gate Output Enable, GOE).

To control the data driving circuit 120, the controller 140 outputs various data control signals DCS including, e.g., a source start pulse (SSP), a source sampling clock (SSC), and a source output enable signal (Source Output Enable, SOE).

The controller 140 may be implemented as a separate component from the data driving circuit 120, or the controller 140, along with the data driving circuit 120, may be implemented as an integrated circuit.

The data driving circuit 120 receives the image data Data from the controller 140 and supply data voltages to the plurality of data lines DL, thereby driving the plurality of data lines DL. The data driving circuit 120 is also referred to as a ‘source driving circuit.’

The data driving circuit 120 may include one or more source driver integrated circuit (SDIC).

Each source driver integrated circuit (SDIC) may include a shift register, a latch circuit, a digital-to-analog converter (DAC), and an output buffer. In some cases, each source driver integrated circuit (SDIC) may further include an analog-digital converter (ADC).

For example, each source driver integrated circuit (SDIC) may be connected with the display panel 110 by a tape automated bonding (TAB) type or connected to a bonding pad of the display panel 110 by a chip on glass (COG) or chip on panel (COP) type or may be implemented by a chip on film (COF) type and connected with the display panel 110.

The gate driving circuit 130 may output a gate signal of a turn-on level voltage or a gate signal of a turn-off level voltage according to the control of the controller 140. The gate driving circuit 130 may sequentially drive the plurality of gate lines GL by sequentially supplying gate signals of the turn-on level voltage to the plurality of gate lines GL.

The gate driving circuit 130 may be connected with the display panel 110 by TAB method or connected to a bonding pad of the display panel 110 by a COG or COP method or may be connected with the display panel 110 according to a COF method. Alternatively, the gate driving circuit 130 may be formed in a gate in panel (GIP) type, in the non-display area NDA of the display panel 110. The gate driving circuit 130 may be disposed on the substrate 111 or may be connected to the substrate 111. In other words, the gate driving circuit 130 that is of a GIP type may be disposed in the non-display area NDA of the substrate 111. The gate driving circuit 130 that is of a chip-on-glass (COG) type or chip-on-film (COF) type may be connected to the substrate 111.

Meanwhile, at least one of the data driving circuit 120 and the gate driving circuit 130 may be disposed in the display area DA. For example, at least one of the data driving circuit 120 and the gate driving circuit 130 may be disposed not to overlap the subpixels SP or to overlap all or some of the subpixels SP.

When a selected gate line GL is driven by the gate driving circuit 130, the data driving circuit 120 may convert the image data Data received from the controller 140 into an analog data voltage and supply it to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides of the display panel 110.

The gate driving circuit 130 may be connected to one side (e.g., a left or right side) of the display panel 110. Depending on the gate driving scheme and the panel design scheme, gate driving circuits 130 may be connected with both the sides (e.g., both the left and right sides) of the display panel 110, or two or more of the four sides of the display panel 110.

The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 120 and the gate driving circuit 130 through the printed circuit board or the flexible printed circuit.

The controller 140 may transmit/receive signals to/from the data driving circuit 120 according to one or more predetermined interfaces. The interface may include, e.g., a low voltage differential signaling (LVDS) interface, an embedded clock point to point interface (EPI), and a serial peripheral interface (SPI).

The controller 140 may include a storage medium, such as one or more registers.

The display device 100 according to embodiments of the disclosure may be a display including a backlight unit, such as a liquid crystal display, or may be a self-emission display, such as an organic light emitting display device, a quantum dot display device, or an inorganic light emitting display device. When the display device 100 according to embodiments of the disclosure is an organic light emitting display device, each subpixel SP may include an organic light emitting diode (OLED), which is self-emissive, as the light emitting element.

When the display device 100 according to embodiments of the disclosure is a quantum dot display device, each subpixel SP may include a light emitting element formed of quantum dots that are semiconductor crystals that emit light by themselves.

If the display device 100 according to embodiments of the disclosure is an inorganic light emitting display device, each subpixel SP may include an inorganic light emitting element, which is self-emissive and formed of an inorganic material, as the light emitting element. For example, the inorganic light emitting element is also called a micro light emitting diode (LED), and the inorganic light emitting display device is also called a micro LED display device.

Referring to FIG. 1, when the display device 100 according to embodiments of the disclosure is a self-emission display, each of the plurality of subpixels SP disposed on the display panel 110 of the display device 100 according to embodiments of the disclosure may include a light emitting element ED and a subpixel circuit for driving the light emitting element ED.

Referring to FIG. 1, the subpixel circuit of each subpixel SP may include a driving transistor DRT, a scan transistor SCT, and a storage capacitor Cst. In this case, as the subpixel circuit of each subpixel SP includes two transistors DRT and SCT and one capacitor Cst, it may be referred to as having a 2T (transistor) 1C (capacitor) structure.

The light emitting element ED may include an anode electrode AND and a cathode electrode CAT and may include a light emitting layer EL positioned between the anode electrode AND and the cathode electrode CAT.

One of the anode electrode AND and the cathode electrode CAT may be a pixel electrode connected to a transistor, such as the driving transistor DRT, and the other may be a common electrode to which the common voltage is applied. Here, the pixel electrode is an electrode disposed in each subpixel SP, and the common electrode is an electrode commonly disposed in all subpixels SP. For example, the common voltage may be a high-potential voltage EVDD which is a high-level common voltage or a low-potential voltage EVSS which is a low-level common voltage. Here, the high-potential voltage EVDD is also referred to as a driving voltage, and the low-potential voltage EVSS is also referred to as a base voltage.

The anode electrode AND may be a pixel electrode connected to a transistor, such as the driving transistor DRT, and the cathode electrode CAT may be a common electrode to which the low-potential voltage EVSS is applied.

For example, the light emitting element ED may be an organic light emitting diode OLED, an inorganic material-based light emitting diode LED, or a quantum dot light emitting element.

The driving transistor DRT is a transistor for driving the light emitting element ED, and may include a first node N1, a second node N2, and a third node N3.

The first node N1 of the driving transistor DRT may be a gate node of the driving transistor DRT, and may be electrically connected with a source node or a drain node of the scan transistor SCT. The second node N2 of the driving transistor DRT may be a source node or a drain node of the driving transistor DRT, and may be electrically connected to the anode electrode AND of the light emitting element ED. The third node N3 of the driving transistor DRT may be electrically connected with a high-potential voltage line DVL supplying a high-potential voltage EVDD.

The scan transistor SCT may be controlled by a scan signal SC, which is a type of gate signal, and may be connected between the first node N1 of the driving transistor DRT and the data line DL. In other words, the scan transistor SCT may be turned on or off according to the scan signal SC supplied from the scan signal line, which is a type of the gate line GL, controlling the connection between the data line DL and the first node N1 of the driving transistor DRT.

The scan transistor SCT may be turned on by the scan signal SC having a turn-on level voltage and transfer the data voltage Vdata supplied from the data line DL to the first node N1 of the driving transistor DRT.

If the scan transistor SCT is an n-type transistor, the turn-on level voltage of the scan signal SC may be a high level voltage. If the scan transistor SCT is a p-type transistor, the turn-on level voltage of the scan signal SC may be a low level voltage. Hereinafter, the scan transistor SCT is exemplified as an n-type transistor. Accordingly, the turn-on level voltage is exemplified as a high-level voltage.

The storage capacitor Cst may be electrically connected between the first node N1 and second node N2 of the driving transistor DRT. The storage capacitor Cst may be charged with the quantity of electric charge corresponding to the voltage difference between both ends thereof and may serve to maintain the voltage difference between both ends for a predetermined frame time. Accordingly, during the predetermined frame time, the corresponding subpixel SP may emit light.

Each of the driving transistor DRT and the scan transistor SCT may be an n-type transistor or a p-type transistor. In the disclosure, for convenience of description, each of the driving transistor DRT and the scan transistor SCT is an n-type transistor.

The storage capacitor Cst is not a parasitic capacitor (e.g., Cgs or Cgd) which is an internal capacitor existing between the gate node and the source node (or drain node) of the driving transistor DRT, but may be an external capacitor intentionally designed outside the driving transistor DRT.

The subpixel SP illustrated in FIG. 1 is merely an example, and various changes may be made thereto, e.g., such as further including one or more transistors or one or more capacitors. Hereinafter, the structure and luminance of the light emitting element ED illustrated in FIG. 1 are described.

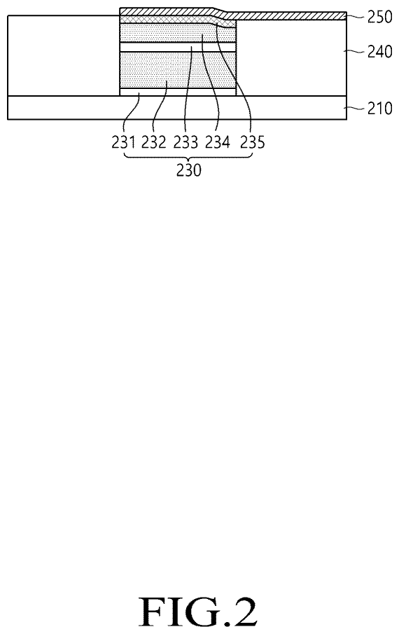

FIG. 2 is a view related to the light emitting element 230 and the surroundings of the light emitting element 230 according to embodiments of the disclosure. Here, the light emitting element 230 may be the light emitting element ED of FIG. 1.

Referring to FIG. 2, a light emitting element lower layer 210 may include the substrate illustrated in FIG. 1 and a plurality of insulation layers. The plurality of insulation layers may be organic layers or inorganic layers.

The light emitting element 230 may include a first electrode 231, a first semiconductor layer 232, a light emitting layer 233, a second semiconductor layer 234, and a second electrode 235.

The first electrode 231 may be disposed on the light emitting element lower layer 210. The first electrode 231 may be a pixel electrode or an anode electrode. The first electrode 231 may include a metallic material. For example, the first electrode 231 may be a transparent metal oxide such as ITO, IGZO, or IZO.

The first semiconductor layer 232 may be disposed on the first electrode 231. The first semiconductor layer 232 may be a layer for injecting holes into the light emitting layer 233. For example, the first semiconductor layer 232 may be a layer doped with a P-type impurity, which is a Group III element such as B, Al, Ga, In, Mg, Zn, or Be, in a material such as gallium nitride (GaN), indium aluminum phosphide (InAlP), or gallium arsenide (GaAs).

The light emitting layer 233 may be disposed on the first semiconductor layer 232. As the light emitting layer 233 is positioned between the first semiconductor layer 232 and the second semiconductor layer 234, the light emitting layer 233 may receive holes and electrons. As the light emitting layer 233 receives holes and electrons, it may emit light. The light emitting layer 233 may be composed of a single layer or a multi-quantum well MQW structure.

The second semiconductor layer 234 may be disposed on the light emitting layer 233. The second semiconductor layer 234 may be a layer for injecting electrons into the light emitting layer 233. For example, the second semiconductor layer 234 may be a layer doped with an N-type impurity, which is a Group V element such as P, As, or Sb, in a material such as gallium nitride (GaN), indium aluminum phosphide (InAlP), or gallium arsenide (GaAs).

The second electrode 235 may be disposed on the second semiconductor layer 234. The second electrode 235 may be a common electrode or a cathode electrode. The second electrode 235 may be a transparent conductive material. For example, the second electrode 235 may be ITO or IZO. The second electrode 235 may be an opaque conductive material. For example, the second electrode 235 may be Ti, Au, Ag, Cu, or an alloy thereof.

The insulation layer 240 may be disposed in a manner surrounding the side surface of the light emitting element 230. The insulation layer 240 may include an organic material. Therefore, referring to FIG. 2, the light emitting element 230 is illustrated as being positioned inside the insulation layer 240. As the insulation layer 240 is positioned on the side surface of the light emitting element 230, the insulation layer 240 may fix the position of the light emitting element 230.

A connection metal pattern 250 may be disposed on the insulation layer 240. The connection metal pattern 250 may be electrically connected to the second electrode 235. The connection metal pattern 250 may be a metal line supplying a base voltage to the second electrode 235.

A schematic description has been provided regarding the structure of the light emitting element 230, and a description will be provided below regarding the viewing angle and luminance of the light emitting element 230.

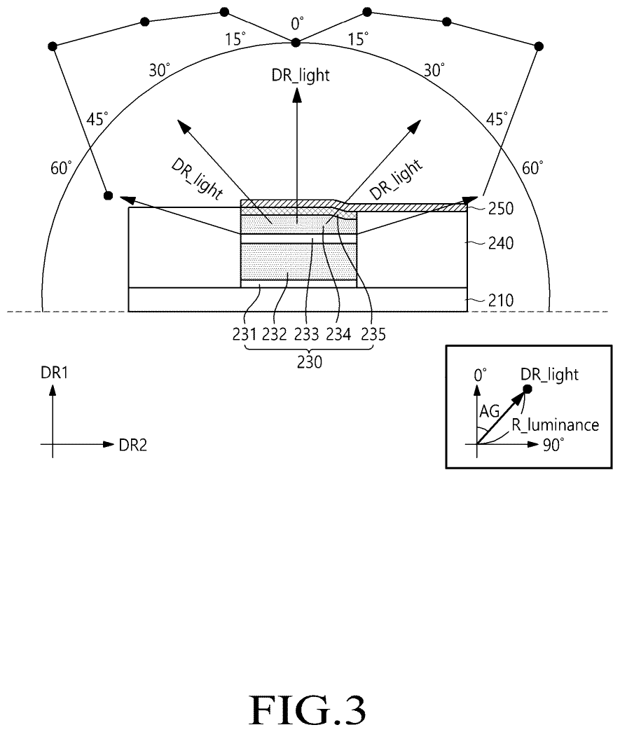

FIG. 3 is a view regarding the viewing angle and luminance of the light emitting element 230 illustrated in FIG. 2.

Referring to FIG. 3, a light emitting layer 233 of the light emitting element 230 may emit light, and the light from the light emitting layer 233 may be emitted at various angles.

For example, a direction DR_light from the light emitting layer 233 toward the second electrode 235 may be referred to as a first direction DR1. An angle between the first direction DR1 and the direction DR_light in which light is emitted may be defined as an emission angle AG. For example, when the emitted light is emitted toward the first direction DR1, the angle of the emitted light may be 0 degrees. When the emitted light is emitted at 30 degrees, 45 degrees, or 60 degrees from the first direction DR1, the emission angle AG may be 30 degrees, 45 degrees, or 60 degrees.

When light propagates at a specific emission angle AG, the light may have a specific luminance. For example, when emitted in the first direction DR1, the luminance ratio R_luminance of the light may be 100%. In other words, when the emission angle AG is 0 degrees, the luminance ratio R_luminance may be 100%. As the emission angle AG changes from 0 degrees to 45 degrees, the luminance ratio R_luminance may gradually increase. However, when the emission angle AG becomes larger than 45 degrees, the luminance ratio R_luminance may decrease due to the insulation layer 240 positioned on the side surface of the light emitting layer 233.

To fix the light emitting element 230, the insulation layer 240 should be disposed around the light emitting element 230, but the insulation layer 240 may reduce the emission luminance of the light emitted from the light emitting element 230.

Accordingly, embodiments of the disclosure may provide a display device capable of stably fixing a light emitting element through a structure with a catching portion and a line surrounding the catching part.

Embodiments of the disclosure may provide a display device capable of enhancing luminance as light emitted from the light emitting element is reflected by the catching portion and the line surrounding the catching portion to be bottom-emitted.

Embodiments of the disclosure may provide a display device capable of enhancing the luminance of light by reflecting the light through a metal.

Embodiments of the disclosure may provide a display device capable of low power consumption by enhancing the luminance of light.

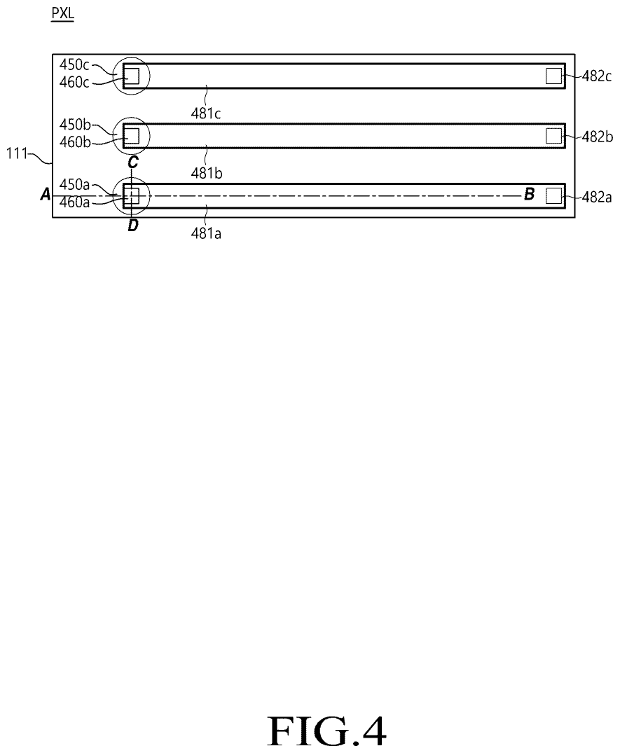

FIG. 4 is a plan view illustrating a pixel according to other embodiments of the disclosure.

Referring to FIG. 4, a pixel PXL may include a first light emitting element 460a, a second light emitting element 460b, and a third light emitting element 460c.

The first light emitting element 460a may emit light of a first color, and the first color may be red. The second light emitting element 460b may emit light of a second color, and the second color may be blue. The third light emitting element 460c may emit light of a third color, and the third color may be green.

The first light emitting element 460a may be positioned on a first catching portion 450a. The second light emitting element 460b may be positioned on a second catching portion 450b. The third light emitting element 460c may be positioned on a third catching portion 450c.

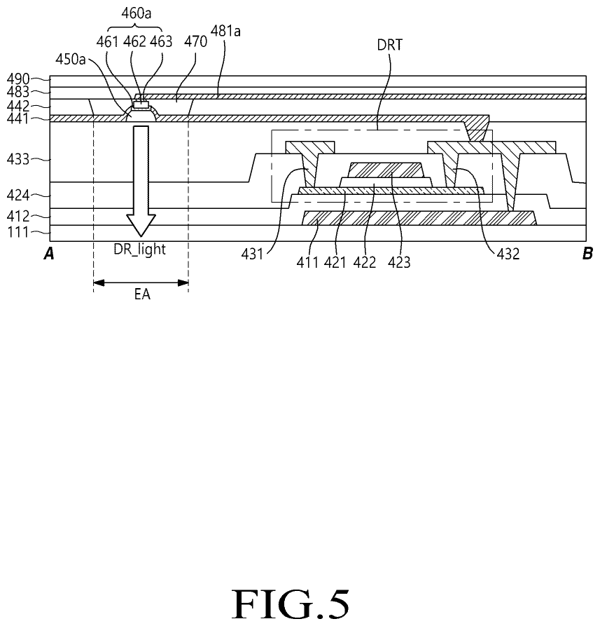

The first catching portion 450a may have a hemispherical cross-section as illustrated in FIG. 5 and a circular plan. Therefore, in the plan view illustrating FIG. 4, the first catching portion 450a is illustrated as circular. Referring to FIG. 4, when viewed based on the plan view, the first light emitting element 460a may be positioned inside the first catching portion 450a, and the center of the first light emitting element 460a may coincide with the center of the first catching portion 450a. The first catching portion 450a may fix the position of the first light emitting element 460a.

The first catching portion 450a may include an organic material, and for example, the first catching portion 450a may include an acrylic-based material or a material based on silicon. The first catching portion 450a may include a non-conductive material. When light, heat, or the like is applied to the first catching portion 450a, the first catching portion 450a may increase in viscosity or become hard.

The characteristics of the second catching portion 450b and the third catching portion 450c may be the same as those of the first catching portion 450a.

Referring to FIG. 4, the light emitting elements 460a, 460b, 460c may be electrically connected to the base lines 481a, 481b, 481c. The base lines 481a, 481b, 481c may be positioned parallel to each other. Referring to the plan view illustrated in FIG. 4, the base lines 481a, 481b, 481c may extend to stretch from the left to the right. The base lines 481a, 481b, 481c may receive a base voltage through metal patterns.

Referring to FIG. 4, the A-B area and the C-D area may be identified. Hereinafter, the A-B area and the C-D area are described.

FIG. 5 is a cross-sectional view of area A-B of FIG. 4.

The substrate 111 may be disposed at the lowermost portion of the display panel 110. The substrate 111 may be a glass substrate or a plastic substrate. The substrate 111 may include a transparent material. Therefore, the direction of light emitted from the first light emitting element 460a disposed on the substrate 111 may be directed toward the lower portion of the substrate 111. In other words, the light emitted from the first light emitting element 460a may pass through the substrate 111 and proceed to the lower surface of the substrate 111.

The light shielding pattern 411 may be disposed on the substrate 111. The light shielding pattern 411 may be disposed under the active pattern 421 of the driving transistor DRT. As the light shielding pattern 411 is disposed under the active pattern 421, it may prevent external light from being incident on the active pattern 421. As the active pattern 421 is not exposed to external light, the material properties of the active pattern 421 may be maintained relatively stable. For example, the distribution state of electrons inside the active pattern 421, the mobility of electrons, or the like may be maintained constantly.

The first insulation layer 412 may be disposed on the substrate 111 and the light shielding pattern 411. The first insulation layer 412 may be disposed to cover the light shielding pattern 411. The first insulation layer 412 may electrically insulate the light shielding pattern 411 from other components. The first insulation layer 412 may include an inorganic material or an organic material.

The active pattern 421 may be disposed on the first insulation layer 412. The active pattern 421 may include an oxide semiconductor material or a silicon semiconductor material or the like. The active pattern 421 may overlap the light shielding pattern 411. The active pattern 421 may be protected from external light by the light shielding pattern 411 disposed under the active pattern 421.

The gate insulation layer 422 may be disposed on the active pattern 421. The gate insulation layer 422 may insulate the active pattern 421 and the gate electrode 423 from each other. The gate insulation layer 422 may include an inorganic material.

The gate electrode 423 may be disposed on the gate insulation layer 422. The gate electrode 423 may include a metallic material.

The second insulation layer 424 may be disposed on the first insulation layer 412. Since the second insulation layer 424 may be deposited over the entire surface on the first insulation layer 412, the second insulation layer 424 may be disposed to cover the active pattern 421, the gate insulation layer 422, and the gate electrode 423. The second insulation layer 424 may include an inorganic material or an organic material.

A first source-drain electrode 431 may be disposed on the second insulation layer 424. The first source-drain electrode 431 may be electrically connected to the active pattern 421 through a contact hole formed in the second insulation layer 424. The first source-drain electrode 431 may include a metallic material.

A second source-drain electrode 432 may be disposed on the second insulation layer 424. The second source-drain electrode 432 may be electrically connected to the active pattern 421 through a contact hole formed in the second insulation layer 424. Further, the second source-drain electrode 432 may be electrically connected to a first driving line 441 through a contact hole formed in the third insulation layer 433.

The second source-drain electrode 432 may be electrically connected to a light shielding pattern 411 through contact holes formed in the first insulation layer 412 and the second insulation layer 424. As the light shielding pattern 411 is electrically connected to the second source-drain electrode 432, the light shielding pattern 411 may not be in a floating state. When the light shielding pattern 411 is in a floating state, the threshold voltage of the driving transistor DRT affected by the light shielding pattern 411 may fluctuate. As the light shielding pattern 411 is not in a floating state, the threshold voltage of the driving transistor DRT may be maintained without fluctuation.

The third insulation layer 433 may be disposed on the second insulation layer 424. The third insulation layer 433 may be disposed to cover the first source-drain electrode 431 and the second source-drain electrode 432. The third insulation layer 433 may include an organic material. In order to flatten the components to be disposed on the third insulation layer 433, an upper surface of the third insulation layer 433 may be formed to be flat.

A first catching portion 450a may be disposed on the third insulation layer 433. The first catching portion 450a may be positioned in the emission area EA. The emission area EA may be an area not overlapping the driving transistor DRT.

The first catching portion 450a may be formed by an inkjet method. For example, an electro hydrodynamic inkjet (EHD) method may be used. The first catching portion 450a may include an insulating material. The first catching portion 450a may have a shape of a hemisphere or a partially truncated sphere. Referring to FIG. 5, a cross-section of the first catching portion 450a in a hemispherical shape may be identified. After the insulating material is applied by an inkjet method, it may be cured by light, heat, or the like.

A first driving line 441 may be disposed on the third insulation layer 433 and the first catching portion 450a. The first driving line 441 may overlap the first catching portion 450a. The first driving line 441 may overlap the first catching portion 450a, but the portion where the first catching portion 450a and the first light emitting element 460a need to contact may be etched and removed.

The first driving line 441 may be disposed to cover the upper surface of a portion of the first catching portion 450a. The first driving line 441 may extend from the highest surface of the first catching portion 450a to a side surface of the first catching portion 450a. Referring to FIG. 5, the first driving line 441 may extend to the left/right along the upper surface of the third insulation layer 433 from the side surface of the first catching portion 450a. A portion of the first driving line 441 may overlap the driving transistor DRT, and the first driving line 441 may be electrically connected to the second source-drain electrode 432 through a contact hole formed in the third insulation layer 433.

The first driving line 441 may include a metallic material. The first driving line 441 may include a material with high reflectivity to reflect light directed toward the first driving line 441. As the first driving line 441 is disposed to cover the first catching portion 450a, the first driving line 441 overlapping the first catching portion 450a may have a shape of a hollow hemisphere or a partially truncated sphere.

A first light emitting element 460a may be disposed on the first catching portion 450a. The first light emitting element 460a may be the light emitting element ED of FIG. 1 and the light emitting element 230 of FIG. 2. The first light emitting element 460a may be disposed on the first catching portion 450a before the first catching portion 450a is completely cured. Therefore, the first light emitting element 460a may be disposed as if embedded in the upper portion of the first catching portion 450a. Referring to FIG. 5, the first catching portion 450a may have a hemispherical shape, but the upper surface of the first catching portion 450a may have a flat recessed shape. The upper surface of the first catching portion 450a may have a flat recessed shape as the first light emitting element 460a is placed on the first catching portion 450a during the formation process, such as the above-described inkjet method.

The first light emitting element 460a may include a first electrode 461, a light emitting layer 462, and a second electrode 463. The first electrode 461 may be disposed on the first catching portion 450a. The first electrode 461 may be a transparent metallic material, e.g., ITO or IZO. The light emitting layer 462 may be disposed on the first electrode 461. The light emitting layer 462 may be formed of a single layer or a multi-quantum well structure, and the light emitting layer 462 may emit light by recombination of electrons and holes. The second electrode 463 may be disposed on the light emitting layer 462. The second electrode 463 may include a metallic material, and the second electrode 463 may be an opaque metal or a transparent metal.

The bank 442 may be disposed on the third insulation layer 433. The bank 442 may include an organic material. The bank 442 may be a layer that defines the emission area EA. The bank 442 may be deposited on the entire surface of the third insulation layer 433 and then partially etched and removed. The emission area EA may correspond to the etched-out area of the bank 442. The first light emitting element 460a may be disposed in the etched-out area of the bank 442. In other words, the first light emitting element 460a may be positioned in the emission area EA. The etched-out area of the bank 442 may have a pit shape or a recess shape.

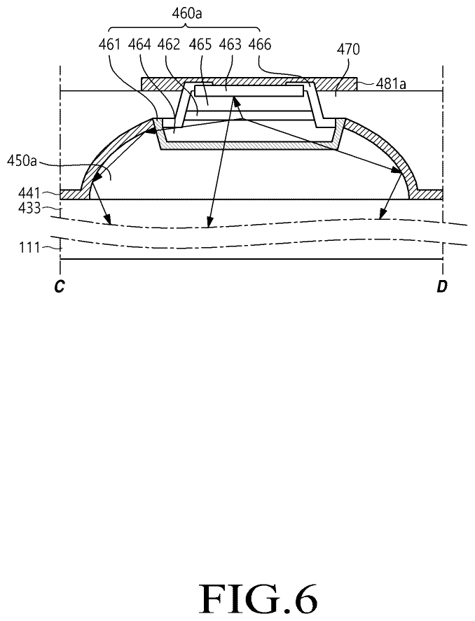

The fourth insulation layer 470 may be disposed to cover the first light emitting element 460a. The fourth insulation layer 470 may be disposed to fill the etched-out area of the bank 442. Inside the etched-out area of the bank 442, the first catching portion 450a, the first driving line 441, the first light emitting element 460a, and the fourth insulation layer 470 may be disposed. Referring to FIG. 5, it may be identified that the first catching portion 450a, the first driving line 441, the first light emitting element 460a, and the fourth insulation layer 470 are disposed inside the etched-out, pit-shaped area of the bank 442 and may have a form that exposes the second electrode 463 in a manner to surround a portion of the side surface of the protective layer 466 (see FIG. 6).

The fourth insulation layer 470 may be disposed adjacent to the periphery of the first light emitting element 460a. The fourth insulation layer 470 may be disposed to fill the etched-out, pit-shaped area of the bank 442. Therefore, the fourth insulation layer 470 may fix the position of the first light emitting element 460a.

In the above description, the bank 442 and the fourth insulation layer 470 are formed separately. However, it is not limited thereto, and the bank 442 and the fourth insulation layer 470 may be formed simultaneously of the same material. In this case, the fourth insulation layer 470 may include an organic material and may be disposed on the third insulation layer 433 to cover the side surface of the first light emitting element 460a and may have a form that exposes the second electrode 463 in a manner to surround a portion of the side surface of the protective layer 466.

The first base line 481a may be disposed on the bank 442. The first base line 481a may be electrically connected to the second electrode 463. The first base line 481a may extend from the portion connected with the second electrode 463 to the upper surface of the fourth insulation layer 470 and the bank 442. The first base line 481a may extend from the upper surface of the fourth insulation layer 470 to the upper surface of the bank 442. The first base line 481a may include a metallic material with high electrical conductivity. The first base line 481a may be an opaque metal or a transparent metal. The first base line 481a may supply a base voltage to the second electrode 463.

The fifth insulation layer 483 may be disposed on the bank 442, the fourth insulation layer 470, and the first base line 481a. The fifth insulation layer 483 may include an organic material or an inorganic material. The fifth insulation layer 483 may cover the first base line 481a. The fifth insulation layer 483 may electrically insulate the first base line 481a.

A cover member 490 may be disposed on the fifth insulation layer 483. The cover member 490 may protect the fifth insulation layer 483 and the components disposed under the fifth insulation layer 483 from the outside. The cover member 490 may include a glass material or a plastic material. The cover member 490 may include a transparent material or an opaque material.

A cross-sectional view of the A-B area illustrated in FIG. 4 has been described above, and a cross-sectional view of the C-D area illustrated in FIG. 4 is described below.

FIG. 6 is a cross-sectional view of area C-D of FIG. 4.

Referring to FIG. 6, the third insulation layer 433 may be disposed on the substrate 111, and the first catching portion 450a may be disposed on the third insulation layer 433. The first catching portion 450a may have a hemispherical shape. Referring to FIG. 6, the first catching portion 450a may have a shape of an upward convex hemisphere or a partially truncated sphere.

Referring to FIG. 6, the first driving line 441 may be disposed on the first catching portion 450a, and the first driving line 441 may be disposed along the perimeter of the first catching portion 450a. The first driving line 441 may extend from the perimeter of the first catching portion 450a to the upper surface of the third insulation layer 433. The first catching portion 450a may have a curved side surface convex upward, and the first driving line 441 may extend along the curved side surface. The first driving line 441 may include an opaque metallic material.

Since a portion of the perimeter of the first catching portion 450a is hemispherical, the first driving line 441 overlapping the first catching portion 450a may have a curved shape.

Referring to FIG. 6, the first light emitting element 460a may be disposed on the first catching portion 450a. The first light emitting element 460a may include a first electrode 461, a first semiconductor layer 464, a light emitting layer 462, a second semiconductor layer 465, a second electrode 463, and a protective layer 466. The first light emitting element 460a may overlap a portion of the first catching portion 450a. The first light emitting element 460a may overlap an upper surface of the first catching portion 450a, and a portion of the first light emitting element 460a may be embedded in the first catching portion 450a.

The first electrode 461 may be disposed on the first catching portion 450a. The first electrode 461 may be dish-shaped, and the side surface and lower portion of the first semiconductor layer 464 may be positioned inside the first electrode 461. The first electrode 461 may have a shape of protrude beyond the outermost portion of the first semiconductor layer 464 to surround the first semiconductor layer 464. The first electrode 461 may be a transparent conductive material or transparent metallic material, e.g., ITO or IZO. The first electrode 461 may be an opaque conductive material, e.g., Ti, Au, Ag, Cu, or an alloy thereof. Light directed toward the first electrode 461 may pass through the first electrode 461 toward the substrate 111.

The first semiconductor layer 464 may be disposed on the first electrode 461. The first semiconductor layer 464 may be a layer for injecting holes into the light emitting layer 462. For example, the first semiconductor layer 464 may be a layer doped with a P-type impurity, which is a Group III element such as B, Al, Ga, In, Mg, Zn, or Be, in a material such as gallium nitride (GaN), indium aluminum phosphide (InAlP), or gallium arsenide (GaAs).

The light emitting layer 462 may be disposed on the first semiconductor layer 464. As the light emitting layer 462 is positioned between the first semiconductor layer 464 and the second semiconductor layer 465, the light emitting layer 462 may receive holes and electrons. As the light emitting layer 462 receives holes and electrons, it may emit light. The light emitting layer 462 may be composed of a single layer or a multi-quantum well MQW structure.

The second semiconductor layer 465 may be disposed on the light emitting layer 462. The second semiconductor layer 465 may be a layer for injecting electrons into the light emitting layer 462. For example, the second semiconductor layer 465 may be a layer doped with an N-type impurity, which is a Group V element such as P, As, or Sb, in a material such as gallium nitride (GaN), indium aluminum phosphide (InAlP), or gallium arsenide (GaAs).

The second electrode 463 may be disposed on the second semiconductor layer 465. The second electrode 463 may be a common electrode or a cathode electrode. The second electrode 463 may include a transparent metallic material. Light directed toward the second electrode 463 may propagate through the second electrode 463. The second electrode 463 may include an opaque metallic material, and light directed toward the second electrode 463 may be reflected by the second electrode 463.

A protective layer 466 may be disposed outside the light emitting layer 462, the second semiconductor layer 465, and the second electrode 463. The protective layer 466 may protect the light emitting layer 462, the first semiconductor layer 464, and the second semiconductor layer 465 from the outside. A portion of the protective layer 466 may be disposed in contact with the first electrode 461. A portion of the protective layer 466 may overlap a side portion of an upper surface of the first semiconductor layer 464. A portion of the protective layer 466 may be disposed in contact with a side surface of the light emitting layer 462. A portion of the protective layer 466 may be disposed in contact with a side surface and a portion of the upper surface of the second semiconductor layer 465. A portion of the protective layer 466 may be disposed in contact with a side surface and a portion of the upper surface of the second electrode 463.

The first semiconductor layer 464, the light emitting layer 462, the second semiconductor layer 465, and the second electrode 463 may have a form surrounded by the first electrode 461 and the protective layer 466, and the first electrode 461 may protrude outward beyond the protective layer 466 to contact the first driving line 441. When viewed in plan view, the diameter of the first electrode 461 may be larger than the diameter of the protective layer 466. A portion of the upper surface of the protective layer 466 may be formed to expose the second electrode 463.

A fourth insulation layer 470 may be positioned outside the first light emitting element 460a. The fourth insulation layer 470 may protect the first light emitting element 460a from external elements while fixing the first light emitting element 460a. The fourth insulation layer 470 may overlap the first driving line 441. Around the first light emitting element 460a, the fourth insulation layer 470 may be disposed to cover the first driving line 441. The fourth insulation layer 470 may overlap the first catching portion 450a.

The first base line 481a may be disposed on the first light emitting element 460a. The first base line 481a may be electrically connected to the second electrode 463. The first base line 481a may supply a base voltage to the second electrode 463. The first base line 481a may include an opaque metallic material. The first base line 481a may reflect light directed toward the first base line 481a.

Referring to FIG. 6, the light emitting layer 462 may emit light to the surroundings of the light emitting layer 462.

Referring to FIG. 6, the light emitted from the light emitting layer 462 may propagate toward the substrate 111. The substrate 111 may include a transparent material, and light emitted from the light emitting layer 462 may pass through the substrate 111 and propagate to the lower portion of the substrate 111.

Referring to FIG. 6, light emitted from the light emitting layer 462 may propagate toward the first driving line 441. Light propagating toward the first driving line 441 may be reflected by the first driving line 441 and then directed toward the substrate 111. The reflected light may pass through the substrate 111 and propagate to the lower portion of the substrate 111.

Referring to FIG. 6, light emitted from the light emitting layer 462 may propagate toward the second electrode 463. Light propagating toward the second electrode 463 may be reflected by the second electrode 463 and then directed toward the substrate 111. The reflected light may pass through the substrate 111 and propagate to the lower portion of the substrate 111.

In other words, light emitted from the light emitting layer 462 may be reflected by components around the light emitting layer 462 and directed toward the substrate 111. As light emitted from the light emitting layer 462 is reflected and propagates to the substrate 111, the amount of light passing through the substrate 111 may increase. In other words, the luminance of light emitted from the light emitting layer 462 may increase. This may be represented as an enhancement in light extraction of the display device, and it may also be represented as an improvement in light extraction of the display device.

A display device according to an embodiment of the disclosure may be described as follows.

Embodiments of the disclosure may provide a display device according to embodiments of the disclosure may comprise a substrate, a first insulation layer disposed on the substrate, a catching portion disposed on the first insulation layer and having a curved side surface convex upward, a light emitting element disposed on the catching portion and overlapping a portion of the catching portion, and a driving line extending along the curved side surface.

The catching portion may include a transparent insulating material.

The catching portion may be formed by an inkjet method.

A viscosity of the catching portion may increase when the catching portion receives light or heat.

The driving line may include an opaque metallic material.

Light directed toward the driving line may be reflected by the driving line.

The light emitting element may overlap an upper surface of the catching portion, and the light emitting element may be embedded in the catching portion.

The light emitting element may include a first electrode overlapping the catching portion, a first semiconductor layer disposed on the first electrode, a light emitting layer disposed on the first semiconductor layer, a second semiconductor layer disposed on the light emitting layer, a second electrode disposed on the second semiconductor layer, and a protective layer positioned outside the light emitting layer, the second semiconductor layer, and the second electrode.

The first electrode may include a transparent metallic material.

Light directed toward the first electrode may pass through the first electrode toward the substrate.

The second electrode may include an opaque metallic material.

Light directed toward the second electrode may be reflected by the second electrode.

Light emitted from the light emitting layer may pass through the substrate and propagate toward a lower portion of the substrate.

The substrate may include a transparent material.

The display device may further comprise a driving transistor disposed on the substrate. The driving transistor may include an active pattern disposed on the substrate, a gate insulation layer disposed on the active pattern, a gate electrode disposed on the gate insulation layer, a first source/drain electrode electrically connected to the active pattern, and a second source/drain electrode electrically connected to the active pattern.

The display device may further comprise a light shielding pattern disposed between the substrate and the driving transistor.

The light shielding pattern may be electrically connected to the first source/drain electrode or the second source/drain electrode.

The display device may further comprise a bank defining an emission area, which is a location where the light emitting element is disposed, a second insulation layer positioned outside the light emitting element in the emission area, and a base line disposed on the second insulation layer and electrically connected to the light emitting element.

The base line may include an opaque metallic material.

The luminance of light after passing through the second insulation layer may be reduced compared to before passing through the second insulation layer.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device comprising:
a substrate;
a first insulation layer disposed on the substrate;
a catching portion disposed on the first insulation layer and having a curved side surface convex upward;
a light emitting element disposed on the catching portion and overlapping a portion of the catching portion; and
a driving line extending along the curved side surface.

2. The display device of claim 1, wherein the catching portion includes a transparent insulating material.

3. The display device of claim 1, wherein the catching portion has a shape of an upward convex hemisphere or a partially truncated sphere.

4. The display device of claim 1, wherein a viscosity of the catching portion increases when the catching portion receives light or heat.

5. The display device of claim 1, wherein the driving line includes an opaque metallic material.

6. The display device of claim 5, wherein light directed toward the driving line is reflected by the driving line.

7. The display device of claim 1, wherein the light emitting element overlaps an upper surface of the catching portion, and a portion of the light emitting element is embedded in the catching portion.

8. The display device of claim 1, wherein the light emitting element includes:
a first electrode overlapping the catching portion;
a first semiconductor layer disposed on the first electrode;
a light emitting layer disposed on the first semiconductor layer;
a second semiconductor layer disposed on the light emitting layer;
a second electrode disposed on the second semiconductor layer; and
a protective layer positioned outside the light emitting layer, the second semiconductor layer, and the second electrode.

9. The display device of claim 8, wherein the first electrode includes a transparent metallic material.

10. The display device of claim 9, wherein light directed toward the first electrode passes through the first electrode toward the substrate.

11. The display device of claim 8, wherein the second electrode includes an opaque metallic material.

12. The display device of claim 11, wherein light directed toward the second electrode is reflected by the second electrode.

13. The display device of claim 8, wherein light emitted from the light emitting layer passes through the substrate and propagates toward a lower portion of the substrate.

14. The display device of claim 1, wherein the substrate includes a transparent material.

15. The display device of claim 1, further comprising a driving transistor disposed on the substrate, wherein the driving transistor includes:
an active pattern disposed on the substrate;
a gate insulation layer disposed on the active pattern;
a gate electrode disposed on the gate insulation layer;
a first source/drain electrode electrically connected to the active pattern; and
a second source/drain electrode electrically connected to the active pattern.
